(19) United States
(12) Patent Application Publication
(10) Pub. No.: US 2007/0054453 A1
(43) Pub. Date: Mar. 8, 2007

(54) Methods of forming integrated circuit memory devices having a charge storing layer formed by plasma doping

(76) Inventors: Gyoung-Ho Buh, Gyeonggi-do (KR); Tai-Su Park, Gyeonggi-do (KR); Chang-Woo Ryoo, Gyeonggi-do (KR); Jong-Ryeol Yoo, Gyeonggi-do (KR); Young-Chang Song, Yongin-si (KR)

Correspondence Address: MYERS BIGEL SIBLEY & SAJOVEC, PO BOX 37428, RALEIGH, NC, 27627, US

(21) Appl. No.: 11/504,023

(22) Filed: Aug. 14, 2006

(30) Foreign Application Priority Data
Sep. 6, 2005 (KR) 2005-82745

(51) Int. Cl. H01L 21/336

(52) U.S. Cl. 438/261; 257/E21.21; 257/E21.423

(57) ABSTRACT

Methods of forming an integrated circuit memory device include forming a dielectric layer on a substrate and forming a charge storing layer on an upper surface of the dielectric layer using a plasma doping process with a remaining portion of the dielectric layer under the charge storing layer defining a tunnel dielectric layer. A blocking dielectric layer is formed on the charge storing layer and a gate electrode layer is formed on the blocking dielectric layer.

### CROSS-REFERENCE TO RELATED APPLICATION

This application is related to and claims priority under 35 U.S.C. § 119 from Korean Patent Application No. 10-2005-0082745, filed on Sep. 6, 2005, in the Korean Intellectual Property Office, the disclosure of which is incorporated herein by reference in its entirety.

### BACKGROUND OF THE INVENTION

The present invention relates to methods of forming integrated circuit devices and, more particularly, to methods of forming memory devices including a charge storing layer.

Non-volatile memory devices are a type of memory device that is capable of storing data even when the power is turned off. Non-volatile memories are used in a wide variety of applications, including some portable storage media products. FLASH memory devices are a widely used type of non-volatile memory device having a floating gate. FLASH memory devices with a stacked gate structure have been used at least in part because they typically may be formed using a relatively simple process. A unit cell of a FLASH memory device with a stacked gate structure may include a sequentially stacked structure including a tunnel oxide layer, a floating gate electrode, a gate interlayer dielectric layer, and a control gate electrode.

The unit cell may further include source/drain regions that are arranged in a substrate at both sides of the floating gate. The floating gate is generally electrically isolated from the source/drain regions and a channel region therebetween. The data stored in the FLASH memory cell may be a logic “1” or “0” depending on a level of charges stored in the floating gate. Charges in the floating gate are generally stored in a “free-charge” state. Accordingly, if a tunnel oxide layer under the floating gate is damaged in a manner affecting the isolation of the floating gate, then all charges stored in the floating gate may be lost. As a result, a FLASH memory cell having a floating gate typically requires a tunnel oxide layer with sufficient thickness to control such unintended loss of charge and corresponding loss of data.

If the thickness of the tunnel oxide layer increases, a reliability of the FLASH memory cell may be improved. However, an operation voltage of the device typically increases with an increasing thickness of the tunnel oxide layer. As a result, a peripheral circuit part (for controlling high voltage) of the FLASH memory device may become more complex. In addition, power consumption of the FLASH memory device may also increase. Furthermore, an operation speed of the FLASH memory device may decrease.

To address one or more of these problems, a SONOS (Silicon-Oxide-Nitride-Oxide-Silicon) device configuration has been suggested. The SONOS memory cell generally includes a tunnel oxide layer, a silicon nitride layer, a top oxide film and a gate electrode, which are stacked sequentially on a substrate.

The SONOS memory cell generally stores charges in the silicon nitride layer. In particular, the silicon nitride layer may include deep level traps, and charges may be stored in the deep level traps. Accordingly, even if the tunnel oxide layer is partially damaged, the SONOS memory cell may only lose a part of the charges in the silicon nitride layer in a region having its isolation affected by the damage. Therefore, it is typically possible to form a tunnel oxide layer thinner with a SONOS device than for the FLASH memory cell having the floating gate described above. As a result, the SONOS memory cell may use a relatively low operation voltage in comparison with the FLASH memory cell. Also, the SONOS memory cell may be more adapted to a large-scale integration application.

Generally, a trap dielectric layer as a charge storing layer is formed by chemical vapor deposition (CVD) process. For example, a charge storing layer formed with a nitride layer typically depends on its nitrogen concentration to control its operation. As such, controlling of the nitrogen concentration in the charge storing layer is desired to facilitate improving the charge storing layers characteristics. Controlling the composition of the charge storing layer may be difficult because of the need to control process parameters, such as a deposition ratio, a processing temperature and/or other processing conditions. As a result, the performance of the SONOS memory cell may deteriorate because of difficulties in forming the charge storing layer with the desired characteristics.

### SUMMARY OF THE INVENTION

Some embodiments of the present invention provide methods of forming an integrated circuit memory device including forming a dielectric layer on a substrate and forming a charge storing layer on an upper surface of the dielectric layer using a plasma doping process with a remaining portion of the dielectric layer under the charge storing layer defining a tunnel dielectric layer. A blocking dielectric layer is formed on the charge storing layer and a gate electrode layer is formed on the blocking dielectric layer.

In other embodiments, forming the charge storing layer is preceded by forming a photoresist mask pattern on the tunneling dielectric layer having an opening thereon exposing the tunneling dielectric layer in a predetermined area and forming the charge storing layer includes forming the charge storing layer in the predetermined area using the photoresist mask pattern. Forming the charge storing layer may include thermal treating the substrate after the plasma doping process. Forming the charge storing layer may include forming the charge storing layer using a plasma including ions of a selected element and at an acceleration energy of about 50 electron volts (eV) to about 5000 eV.

In further embodiments, the selected element is a nitrogen element. The nitrogen element may be nitrogen gas (N₂), ammonia gas (NH₃) and/or nitrogen tri-fluroride gas (NF₃). A dose amount of the nitrogen element may be about 1×10¹⁴/cm² to about 1×10¹⁷/cm². The selected element may be boron gas, arsenic gas and/or phosphorous gas. Forming the charge storing layer may include rapid thermal treating the substrate after the plasma doping process at a temperature from about 800° C. to about 1100° C. in an atmosphere including oxygen, nitrogen, ammonia and/or hydrogen. Forming a dielectric layer may include forming a single dielectric layer having a thickness selected to result in a desired thickness of the tunnel oxide layer and the charge storing layer.

In other embodiments, forming a dielectric layer includes forming a first dielectric layer and forming a second dielectric layer on the first dielectric layer. The charge storing layer is formed in the second dielectric layer. Forming a first dielectric layer may include thermal oxidizing the substrate and forming the second dielectric layer may include forming the second dielectric layer using a chemical vapor deposition (CVD) process.

In further embodiments, forming a dielectric layer includes forming a lower dielectric layer and forming a high-k dielectric layer on the lower dielectric layer. Forming the charge storing layer includes exposing the high-k dielectric layer to a plasma including ions of a selected element to increase a density of trap sites in the high-k dielectric layer. The high-k dielectric may be, for example, silicon nitride, hafnium oxide, tantalum oxide, titanium oxide and/or aluminum oxide. Forming the lower dielectric layer may include thermal oxidizing the substrate and forming the high-k dielectric layer may include forming the high-k dielectric layer using a chemical vapor deposition (CVD) process.

In yet other embodiments, the selected element is an element selected from group 4 of the periodic table and forming a charge storing layer includes thermal treating the substrate after the plasma doping process to form nano-crystallization particles defining the charge storing layer. The selected element may be, for example, carbon gas, silicon gas and/or germanium gas. The selected element may be a source gas of silane (SiH4), silicon tetracholoride (SiCl4), silicon tetrafluoride (SiF4), germanium tetrahydride (GeH4), germanium fluoride (GeF4), methane (CH4) and/or ethane (C2H6). Thermal treating the substrate may include rapid thermal treating the substrate at a temperature from about 800° C. to about 1100° C. in an atmosphere including oxygen, nitrogen, ammonia and/or hydrogen to form the nano-crystallization particles defining the charge storing layer.

In other embodiments, a dose amount of the selected element is about 1×10¹⁴/cm² to about 1×10¹⁷/cm². Forming a dielectric layer may include forming a single dielectric layer having a thickness selected to result in a desired thickness of the tunnel oxide layer and the charge storing layer. Forming a dielectric layer may include forming a first dielectric layer and forming a second dielectric layer on the first dielectric layer and forming the charge storing layer may include forming the nano-crystallization particles in the second dielectric layer.

In yet further embodiments, the methods further include forming source and drain regions in the substrate on respective sides of the gate electrode layer. In yet other embodiments, methods of forming an integrated circuit memory device include forming a dielectric layer on a substrate. A common gate electrode is formed on the dielectric layer. A charge storing layer is formed on an upper surface of the dielectric layer using an anisotropic plasma doping process and using the common gate electrode as a mask. A portion of the dielectric layer that is under the common gate electrode defines a common gate dielectric layer. A blocking dielectric layer is formed on the charge storing layer and the common gate electrode and control gate electrodes are formed on the blocking dielectric layer on opposite sides of the common gate electrode.

In other embodiments, forming the charge storing layer includes thermal treating the substrate after the plasma doping process. Forming the charge storing layer may include forming the charge storing layer using a plasma including ions of a selected element at an acceleration energy of about 50 electron volts (eV) to about 5000 eV. Forming the charge storing layer may include forming the charge storing layer at a pressure of no more than about 30 mtorr. Forming the charge storing layer may include forming the charge storing layer using a plasma not including hydrogen.

In further embodiments, the selected element is a nitrogen element. The dielectric layer may be silicon oxide (SiO2). The blocking dielectric layer may be a metal oxide. The control gate electrode layer may be a doped poly-silicon layer and/or a metal layer. The control gate electrode layer may be tungsten (W), molybdenum (Mo), titanium (Ti), tantalum (Ta), cobalt (Co), nickel (Ni) and/or a nitride or silicide thereof. The common gate electrode may be formed of a same material as the control gate electrode layer.

### BRIEF DESCRIPTION OF THE DRAWINGS

The above and other features and advantages of the present invention will become more apparent by describing in detail exemplary embodiments thereof with reference to the attached drawings in which:

FIGS. 1a through 6a and 1b through 6b are cross-sectional views illustrating methods of forming an integrated circuit memory device according to some embodiments of the present invention.

FIGS. 7a through 9a and 7b through 9b are cross-sectional views illustrating methods of forming an integrated circuit memory device according to further embodiments of the present invention.

FIGS. 10 through 14 are cross-sectional views illustrating methods of forming an integrated circuit memory device according to other embodiments of the present invention.

FIGS. 15 through 16 are cross-sectional views illustrating methods of forming an integrated circuit memory device according to some embodiments of the present invention.

### DETAILED DESCRIPTION OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

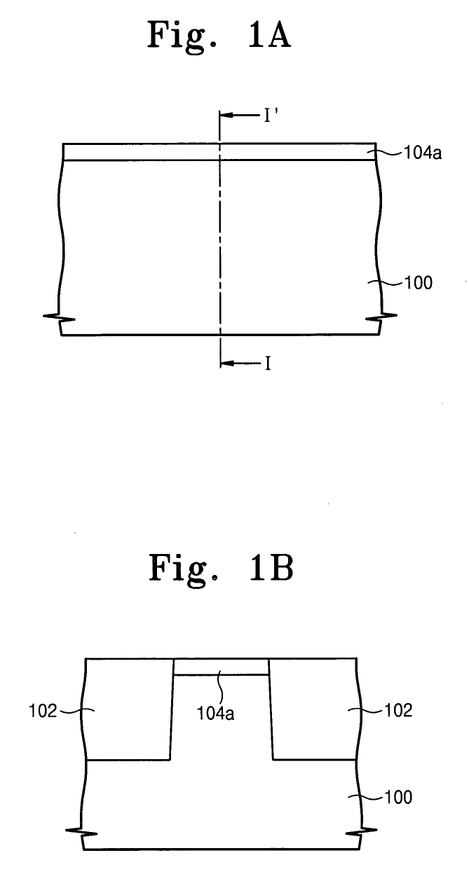

Some embodiments of the present invention will now be described with reference to FIGS. 1a through 6a and 1b through 6b. FIGS. 1a through 6a are cross sectional views taken along a first line. FIGS. 1b through 6b are cross sectional views taken along a second line substantially orthogonal to the corresponding views of FIGS. 1a through 6a.

Referring first to FIGS. 1a and 1b, an active area is defined by forming an isolation layer 102. in an integrated circuit (semiconductor) substrate 100. For example, the isolation layer 102 may be a trench type isolation area including silicon oxide. A tunnel dielectric layer 104a is formed on the substrate 100 over the active area. The tunnel dielectric layer 104a may be a silicon oxide (SiO2) layer. The tunnel dielectric layer 104a may be a thermal oxide formed by a thermal oxidation process.

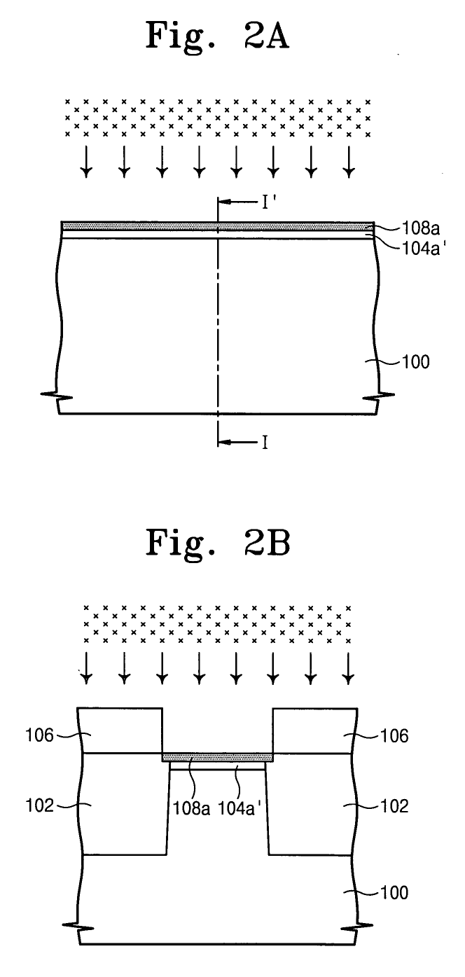

Referring now to FIGS. 2a and 2b, a mask pattern 106 is shown formed on the substrate 100. The mask pattern 106 includes an opening therein over the active area as seen in FIG. 2b. In particular, the opening in the mask pattern 106 exposes the tunnel dielectric layer 104a in a predetermined area or region where a charge storage layer will be formed. The mask pattern 106 covers a peripheral area around the exposed area. The mask pattern 106 can be formed, for example, with photo-resist when using a plasma doping process as described herein. In contrast, the higher temperatures associated with such processes as chemical vapor deposition (CVD) may preclude the use of photo-resist. A cell of the non-volatile memory is formed over an exposed active area of tunnel dielectric layer 104a.

As further illustrated schematically by the arrows in the embodiments of FIGS. 2a and 2b, a plasma doping process is carried out on the integrated circuit substrate 100 having the mask pattern 106. The plasma doping process may thereby be performed to dope an upper portion of the tunnel dielectric layer 104a to form a charge storing layer 108a in the upper portion. After plasma doping, a portion 104a′ of the tunnel dielectric layer 104a remains under the doped charge storing layer 108a, which portion 104a′ may be referred to herein as a “tunnel oxide layer” or “actual tunnel dielectric layer.”

In some embodiments of the present invention, the plasma doping process includes loading the integrated circuit substrate 100 into a process chamber where the plasma doping process will be performed. A source gas in a plasma state is introduced over the substrate 100 in the process chamber. The source gas in some embodiments includes an ion component and/or an ion radical of a selected element. The plasma state source gas may be formed after a source gas is introduced into the process chamber and after plasma energy is supplied into the process chamber to transform the source gas into a plasma state.

In other embodiments, the source gas having the plasma state can be supplied into process chamber after being transformed into the plasma state outside of the process chamber. The source gas having the plasma state can be formed, for example, by using a radio frequency and/or a microwave and/or a direct voltage may be supplied at both ends of a cathode and anode.

The ions of the selected element in the plasma source gas are accelerated and then implanted on the exposed region above the tunnel dielectric layer 104a to form the charge storing layer 108a on the exposed region above the tunnel dielectric layer 104a. The ions are accelerated toward the substrate 100 and may collide with other gas molecules. The acceleration may be provided by an electric field inside a plasma sheath on the cathode. The plasma doping process may result in anisotropic and/or isotropic doping of the specified ions in various embodiments. The ions of the selected element of the source gas are implanted in some embodiments at an acceleration energy of about 50 electron volts (eV) to about 5000 eV.

One of the ion elements may be Nitrogen (N₂). In other words, the charge storing layer 108a can be formed as a nitride layer. The charge storing layer 108a can also include oxygen elements, particularly where the tunnel dielectric layer 104a is formed as a thermal oxide layer. In some embodiments, the dose amount of a selected element in the source gas, such as a nitrogen element, is from about 1×10¹⁴/cm² to about 1×10¹⁷/cm². In some embodiments, the dose amount can be readily controlled from the low dose amount to the high dose amount using the plasma doping process. In some embodiments where a selected dosing element is a nitrogen element, the nitrogen element may be nitrogen gas (N₂), ammonia gas (NH₃) and/or Nitrogen tri-fluroride gas (NF₃).

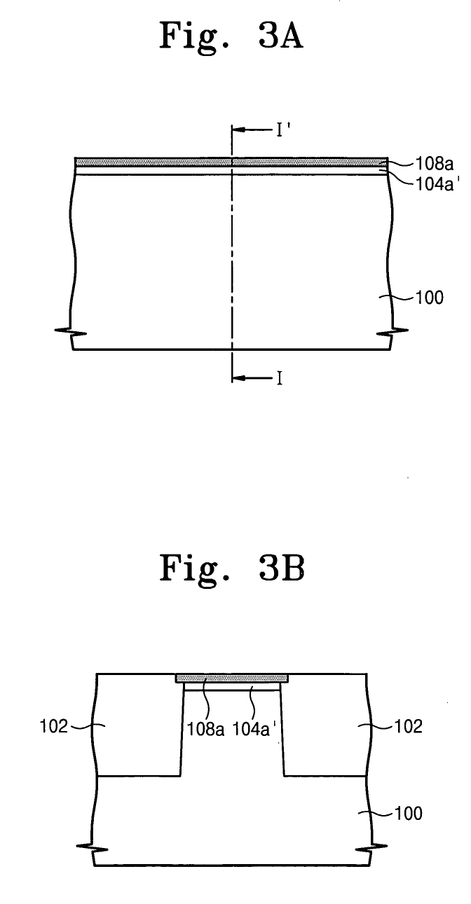

FIGS. 3a and 3b show the substrate 100 after removal of the mask pattern 106 following the plasma doping process. In some embodiments, the substrate 100 with the mask pattern 106 removed is treated to improve the electrical characteristics of the charge storing layer 108a. In some embodiments, the further treatment includes a thermal treatment. The thermal treatment may be a Rapid Thermal Process (RTP) performed at a temperature of about 800° C. to about 1100° C. The thermal treatment may be performed in an oxygen gas, nitrogen gas, ammonia gas and/or hydrogen gas atmosphere. As a result of the thermal treatment, diffusion of the plasma doping process selected element ions to the tunnel oxide layer 104a′ may be limited or even prevented.

As the charge storing layer 108a is formed by the plasma doping process, the element concentration of the charge storing layer 108a, such as nitrogen (N₂), may be easily adjusted by controlling a dose amount of the plasma doping process. As a result, the characteristics of the charge storing layer 108a can be improved in some embodiments of the present invention.

In some embodiments, a high concentration of ions in the charge storing layer 108a is desired. For example, because the trapping density is generally increased in the charge storing layer 108a as a result of the high concentration, the charge storing capacity per unit area of a memory device including the charge storing layer 108a may be improved. Therefore, a non-volatile memory cell including the charge storing layer 108a may store a large amount of an electric charge even if a plane area occupied by the cell is decreased. This may be particularly beneficial for highly integrated non-volatile memory devices.

Furthermore, using a plasma doping process, the implanted element may be implanted at a low acceleration energy level. As a result, the plasma doping process may be precisely performed in the upper portion of the tunnel dielectric layer 104a with less variation in implantation depth. In other words, the charge storing layer 108a can be formed using the plasma doping process while reducing and/or minimizing deterioration of the characteristics of the underlying actual tunnel dielectric layer 104a′. Also, the charge storing layer 108a can be selectively formed in a selected region of the substrate 100. In some embodiments, the selective formation may utilize anisotropic characteristics of a plasma doping process having selected operating conditions and/or by using the mask pattern 106.

A source gas used in the plasma doping process can include nitrogen as well as another source gas. For example, a source gas of the plasma doping process may be an element selected from group 4 of the periodic table. In some embodiments, the source gas for the plasma doping process can be one or more of carbon gas, silicon gas and/or germanium gas. In such embodiments a source gas or gases including element(s) selected from group 4 of the periodic table may be used to selectively implant the selected element(s) into the upper portion of the tunnel dielectric layer 104a using the mask pattern 106.

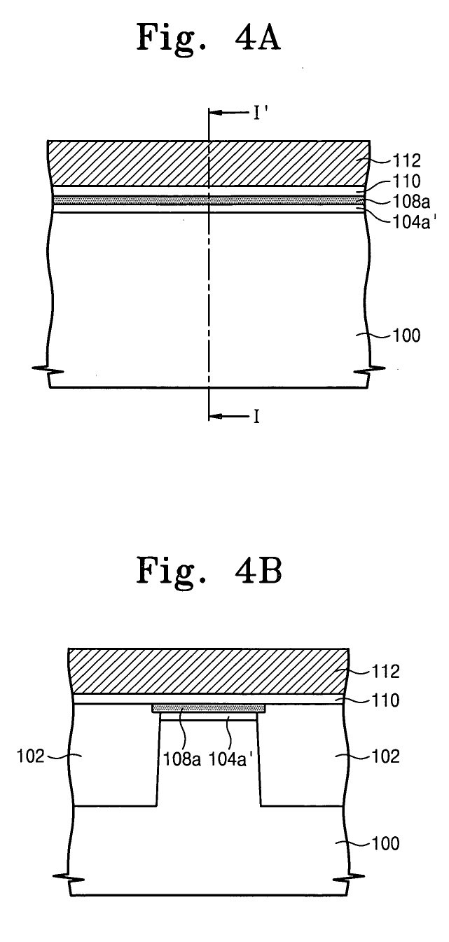

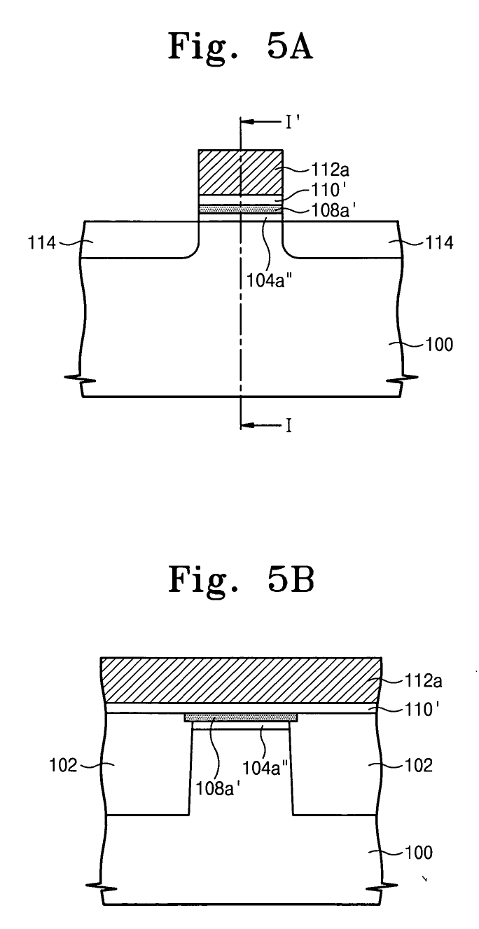

After the formation of the charge storing layer 108a, further processes may be performed as will be described with reference to FIGS. 4a, 5a and 4b, 5b. Referring first to FIGS. 4a and 4b, a blocking dielectric layer 110 is shown formed on the substrate 100 including the charge storing layer 108a. The blocking dielectric layer 110 may be formed conformally. The blocking dielectric layer 110 may be formed of silicon oxide in some embodiments. In some embodiments, the blocking dielectric layer 110 is thicker than the actual tunnel dielectric layer 104a′. The blocking dielectric layer 110 may also be formed of a dielectric layer having a higher dielectric constant than that of the actual tunnel dielectric layer 104a′.

In some embodiments, the blocking dielectric layer 110 is formed of a metal oxide, such as aluminum oxide and/or hafnium oxide and the metal oxide layer may be a single layer structure or a multi-layer structure.

A conductive control gate electrode layer 112 is shown formed on the blocking dielectric layer 110. The gate electrode layer 112 may be formed of one or more of doped poly-silicon and/or a metal, such as tungsten (W), molybdenum (Mo), titanium (Ti), tantalum (Ta), cobalt (Co), nickel (Ni) and/or a conductive metal nitride (such as TiN or WN) and/or metal silicide (such as WSi or CoSi or NiSi or TiSi) thereof.

The control gate electrode layer 112, the blocking dielectric layer 110, the charge storing layer 108a and the tunnel dielectric layer 104a may be patterned to form the structure illustrated in FIGS. 5a and 5b. As such, the tunnel dielectric layer pattern 104a″, the charge storing layer pattern 108a′, the blocking dielectric layer pattern 110′ and the control gate electrode 12a may be formed. In some embodiments, the blocking dielectric layer 110, the charge storing layer 108a and/or the tunnel dielectric layer 104a′ may be formed so as to remain on both sides of the control gate electrode 112a as will be described further later herein.

An impurity doped layer (or doped regions) 114 may be formed in the substrate 100 proximate respective sides of the control gate electrode 112a using the control gate electrode as a mask. The doped regions 114 may define source/drain regions of a transistor of a memory cell.

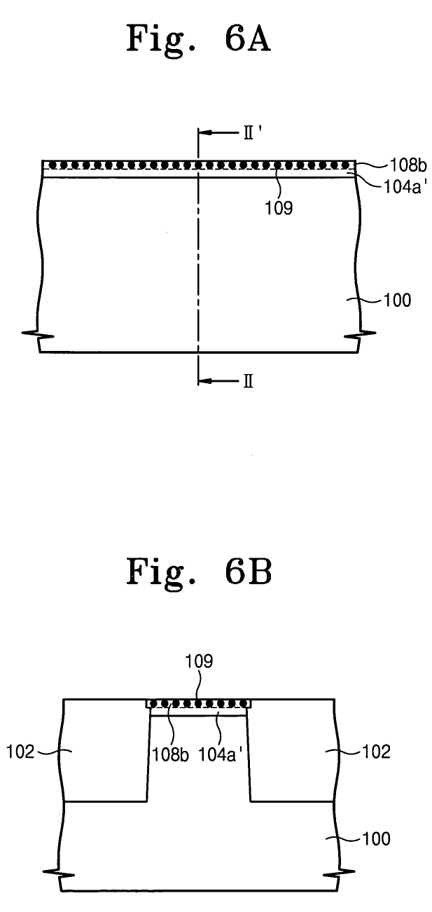

FIGS. 6a and 6b illustrate operations following removal of the mask pattern (106) after the plasma doping process when the selected element of the source gas is selected from group 4 of the periodic table. As shown schematically in FIGS. 6a and 6b, a thermal treatment process is performed to form nano-crystallization particles 109 in a charge storing layer 108b. More particularly the element(s) selected from group 4 of the periodic table implanted into the charge storing layer 108b by the plasma doping process are condensed and the nano-crystallization particles 109 may be formed. The nano-crystallization particles 109 may form traps that can catch electric charges. The nano-crystallization particles may be formed where the selected element in the plasma is carbon gas, silicon gas and/or germanium gas (i.e., a source gas including an element from group 4 of the periodic table is used in the plasma doping process). In some embodiments, the source gas that includes one (or more) of the elements from group 4 of the periodic table as a component may be a source gas of silane (silicontetrahydride (SiH4)), silicon tetracholoride (SiCl4), silicon tetrafluoride (SiF4), germanium tetrahydride (GeH4), germanium fluoride (GeF4), methane (CH4) and/or ethane (C2H6).

The thermal treatment to form the nano-crystallization particles 109 may be a RTP (Rapid Thermal Process) at a temperature from about 800° C. to about 1100° C. The thermal treatment may be performed in an atmosphere including an oxygen gas, nitrogen gas, ammonia gas and/or hydrogen gas. As a result of the thermal treatment, diffusion of the plasma doping elements into the actual tunnel dielectric layer 104a′ may be limited or even prevented.

The charge storing layer 108b may be formed to provide charge storing characteristics similar to those of the charge storing layer 108a described with reference to FIGS. 3a and 3b using the plasma doping process. For example, the concentration of the element selected from group 4 of the periodic table may be readily adjusted and the charge storing layer 108b may be selectively formed in a predetermined region using anisotropy in the plasma doping process and/or a mask pattern.

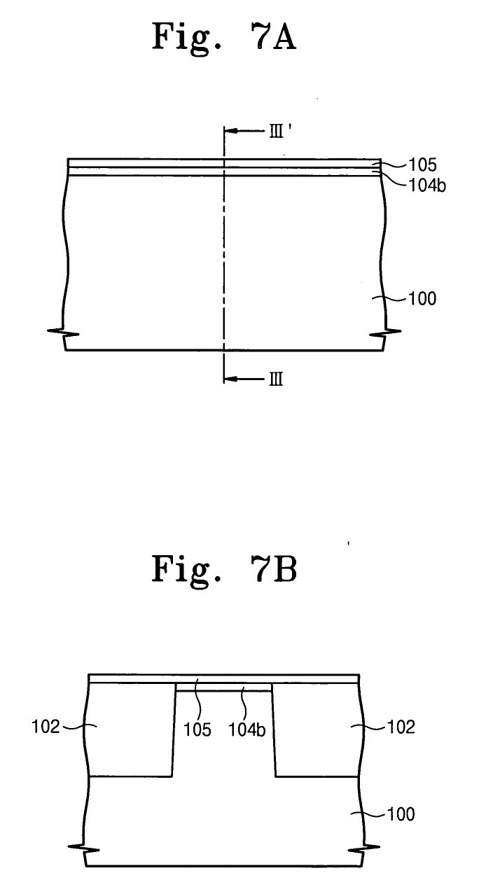

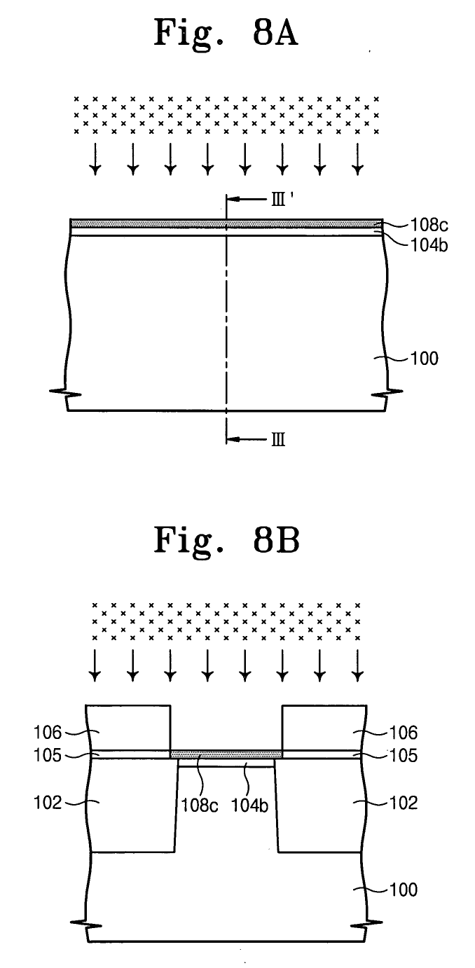

Further embodiments of the present invention will now be described with reference to FIGS. 7a, 7b, 8a and 8b. As shown in FIGS. 7a and 7b, a tunnel dielectric layer 104b is formed in an integrated circuit substrate 100 over an active area therein defined by an isolation layer 102. The tunnel dielectric layer 104b may be formed, for example, with thermal oxide. In other words, the tunnel dielectric layer 104b may be formed of the same material as the tunnel dielectric layer 104a described previously with reference to FIGS. 1a and 1b. As seen by comparing FIGS. 1a, 1b and 7a, 7b, a thickness of the tunnel dielectric layer 104b may be thinner than that of the tunnel dielectric layer 104a. In addition, a buffer layer 105 is shown formed over the tunnel dielectric layer 104b on the substrate 100. The buffer layer 105 may be conformally formed.

A predetermined area of buffer layer 105 is exposed by an opening in the mask pattern 106. As illustrated in FIGS. 8a and 8b, a charge storing layer 108c is formed on the substrate 100 using the plasma doping process as will now be described. One or more selected elements in the plasma doping process are implanted into the exposed area of the buffer layer 105 and the charge storing layer 108c is formed. The element(s) in the plasma doping process may also be implanted into an upper portion of the tunnel dielectric layer 104b in some embodiments.

The plasma doping process method may proceed in a manner substantially the same as described previously with reference to FIGS. 2a and 2b. For example, a selected element in the source gas may be a nitrogen element (N₂). The charge storing layer 108c may, thus, be formed with a nitride layer, which may include nitrogen and silicon elements and may further include oxygen elements, for example, where the buffer layer 105 is formed as a silicon oxide layer. The charge storing layer 108c may be formed as a nitride layer including nitrogen and silicon elements without oxygen elements, for example, where the buffer layer 105 is formed as a silicon layer. When the buffer layer 105 is formed with silicon, the mask pattern 106 may be removed after the formation of the charge storing layer 108c and an un-reacted silicon layer of the buffer layer 105 is removed, for example, by using the etching selectivity between the silicon layer and the charge storing layer 108c.

In further embodiments, the buffer layer 105 may be formed as a nitride layer. In this case, the plasma doping process may be used to implant a selected element or elements, such as nitrogen, to control nitrogen concentration of the charge storing layer 108c. As a result, as with the embodiments described previously, trap density of the charge storing layer 108c may be increased and the characteristics of the charge storing layer 108c may be improved.

After performing the plasma doping; process described with reference to FIGS. 8a and 8b, the mask pattern 106 may be removed and the substrate 100 may be heat treated to anneal the charge storing layer 108c. The heat treatment and temperature used therein may be substantially the same as described previously with reference to FIGS. 3a and 3b.

In some embodiments, the concentration of the charge storing layer 108c may be readily controlled and the charge storing layer 108c may be selectively formed. Furthermore, for the embodiments of FIGS. 7a, 7b, 8a and 8b, the tunnel dielectric layer 104b may be formed thinner than the layer 104a because the charge storing layer 108c is formed primarily or entirely in the buffer layer 105. In some embodiments, the tunnel dielectric layer 104b may be formed as a thermal oxide using a thermal oxidation process, which may be a slower process than, for example, chemical vapor deposition (CVD), but may provide better results for a tunnel dielectric layer. As such, the manufacturing time of the device may be reduced because of the thinner thickness of the tunnel dielectric layer 104b as compared to the layer 104a. This, reduced manufacturing time may result where the tunnel dielectric layer 104b is formed with thermal oxide and with thinner thickness and the buffer layer 105 is formed by a CVD process. In addition, the characteristics of the charge storing layer 108c may be improved for particular applications by changing the material of the buffer layer 105 and controlling an ingredient or/and an ingredient ratio in the charge storing layer 108c.

In some embodiments, a majority of the buffer layer 105 is transformed into the charge storing layer 108c to minimize the characteristics deterioration of the tunnel dielectric layer 104b. In other words, the thickness of the actual effective tunnel dielectric layer may be controlled by the thickness of the layer 104b with little to no additional tunnel dielectric layer increase provided by the buffer layer 105 after formation of the charge storing layer 108c therein.

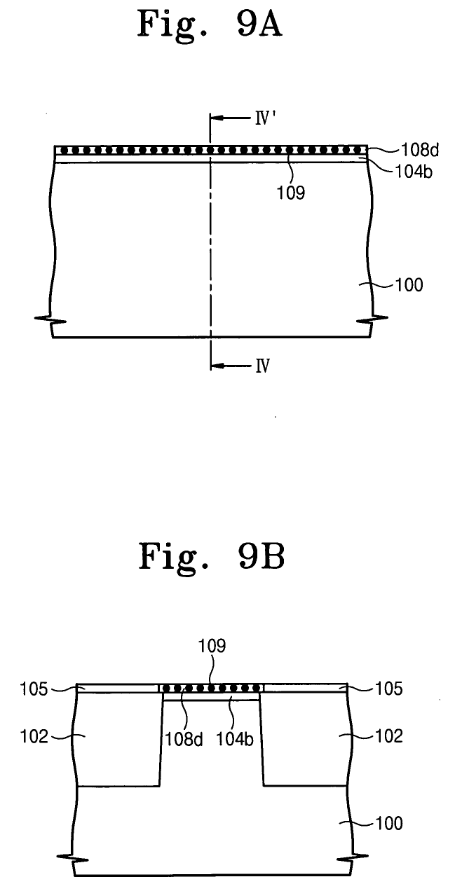

The source gas for the plasma doping process may be a carbon gas, silicon gas and/or germanium gas in some embodiments the plasma doping process may implant an element selected from group 4 of the periodic table into the buffer layer 105 as will be described with reference to FIGS. 9a and 9b. The buffer layer 105 is silicon oxide for some embodiments where the source gases includes element(s) selected from group 4 of the periodic table. The element(s) selected form group 4 of the periodic table may also be implanted into an upper portion of the tunnel dielectric layer 104b in some embodiments. The plasma doping process may be selectively performed using the mask pattern 106 and/or anisotripic properties of a selected plasma doping process.

After the plasma doping process using the source gas including element(s) selected from group 4 of the periodic table is performed, the mask pattern 106 may be removed and a thermal treatment may be performed on the substrate 100. As a result, one or more elements selected from group 4 of the periodic table that were implanted into the charge storing layer 108d during plasma doping may be condensed and nano-crystallization particles 109 may be formed. The thermal treatment process used for the embodiments illustrated in FIGS. 9a and 9b may be substantially the same as that described with reference to FIGS. 3a and 3b.

The source gas including element(s) selected from group 4 of the periodic table may be substantially the same as those described with reference to FIGS. 6a and 6b. As a result, similar effects as described for the previous embodiments may be obtained by forming the charge storing layer 108d using the plasma doping process. For example, the concentration of the element(s) selected from group 4 of the periodic table may be readily controlled and the charge storing layer 108d may be selectively formed. The tunnel dielectric layer 104b may be formed thinner than the layer 104a as the charge storing layer 108d is formed mostly or entirely using the buffer layer 105. Thus, as described with reference to FIGS. 7a, 7b, 8a and 8b, the manufacturing time may be reduced and the deterioration of characteristics of the tunnel dielectric layer 104b may be reduced or minimized.

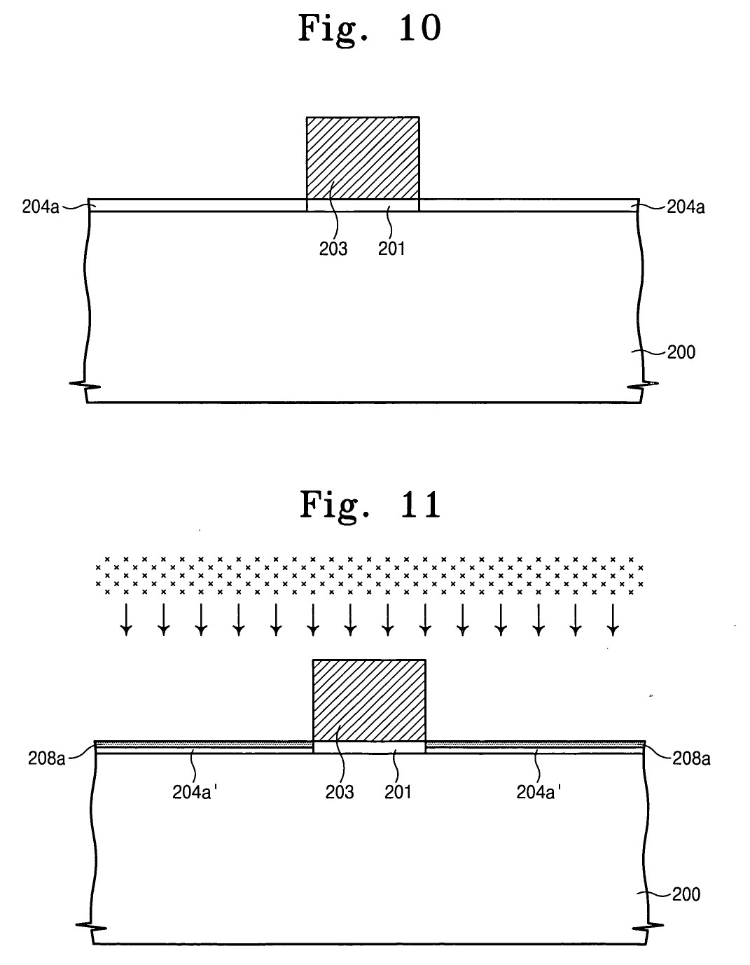

Further embodiments will now be described with reference to the cross-sectional illustrations of FIGS. 10-14. Referring first to FIG. 10, an active area is defined in an integrated circuit (semiconductor) substrate 200 by the formation of an isolation layer. While only an active area region is shown in FIGS. 10-14, it will be understood that the isolation layer may be substantially the same as the isolation layer 102 shown for the previously described embodiments.

A gate dielectric layer 201 and a common gate electrode 203 are shown formed over the active area In FIG. 10. The gate dielectric layer 201 may be formed, for example, of silicon oxide, such as a thermal oxide layer formed by a thermal oxidation process. The common control gate electrode 203 may be formed of one or more of a doped poly-silicon, a metal (e.g., W and/or Mo), a conductive metal nitride (e.g., TiN and/or WN) and/or a metal silicide (e.g., Wsi, CoSi, NiSi and/or TiSi). The active area of the common gate electrode 203 may then be exposed, for example, using cleaning process. A tunnel dielectric layer 204a is also shown in FIG. 10 formed over the exposed active area. The tunnel dielectric layer 204a may be formed, for example, of a thermal oxide.

Referring now to FIG. 11, a plasma doping process is performed on the substrate 200 including the tunnel dielectric layer 204a and common gate electrode 203. The plasma doping process may proceed, for example, substantially the same as described with reference to FIGS. 1a to 6a and 1b to 6b. For example, the source gas for the plasma doping process can be one or more of a nitrogen gas or an element(s) selected from 4 group 4 of the periodic table as discussed previously. In some embodiments, where the source gas includes element(s) selected from group 4 of the periodic table as a component, the source gas may include one or more of silane (silicontetrahydride (SiH₄)), silicon tetrachloride (SiCl₄), silicon tetrafluoride (SiF₄), germanium tetrahydride (GeH₄), germanium fluoride (GeF₄), methane (CH₄) and/or ethane (C₂H₆).

Operations for the plasma doping process will now be further described for some embodiments. The substrate 200 is loaded into a process chamber where the plasma doping process will be performed. A source gas in the plasma state is introduced over the substrate 200 in the process chamber. The method used to provide the source gas in the plasma state over the substrate 200 may be substantially the same as described previously for various embodiments.

Some ions in the plasma source gas are accelerated toward and then implanted an the exposed region of an upper portion of the tunnel dielectric layer 204a. Thus, as illustrate in FIG. 11, a charge storing layer 208a may be formed on the substrate 200 with a remaining portion 204a′ of the tunnel dielectric layer 204a therebetween. The remaining portion 204a′ may be referred to herein as the actual tunnel dielectric layer.

The plasma doping process may be calibrated to be a substantially anisotropic process, with limited or no implanting of ions into sidewalls of the common gate electrode 203. Thus, the charge storing layer 208a may be formed on the substrate 200 on both sides of the common gate electrode 203.

As noted above both sidewalls of the common gate electrode 203 may be provided without the charge storing layer 208a formed therein using an anisotropic plasma doping process. In particular, operating conditions may be selected to provide an anisotropic plasma doping process so the ions in the source gases in the plasma doping process are implanted with anisotropy. For example, in some embodiments the plasma doping process is carried out at an acceleration energy of about 50 electron volts (eV) to about 5000 eV and at a pressure of no more than about 30 mTorr. Lower pressure may provide a more anisotropic plasma doping process, particularly at lower acceleration energies. In some embodiments, plasma doping is performed using a source gas not including a hydrogen based element to increase the anisotropy of the plasma doping process.

After the plasma doping process is performed, a thermal treatment process may be carried out on the substrate 200. The thermal treatment process may be substantially the same as described previously with reference to FIGS. 3a and 3b. In some embodiments where the doping element is nitrogen, the charge storing layer 208a may be annealed in the thermal treatment process. In some embodiments where the doping element is selected from group 4 of the periodic table, the ions of an element(s) selected from group 4 of the periodic table in the charge storing layer 208a may be condensed and numerous nano-crystallization particles may be formed by the thermal treatment process.

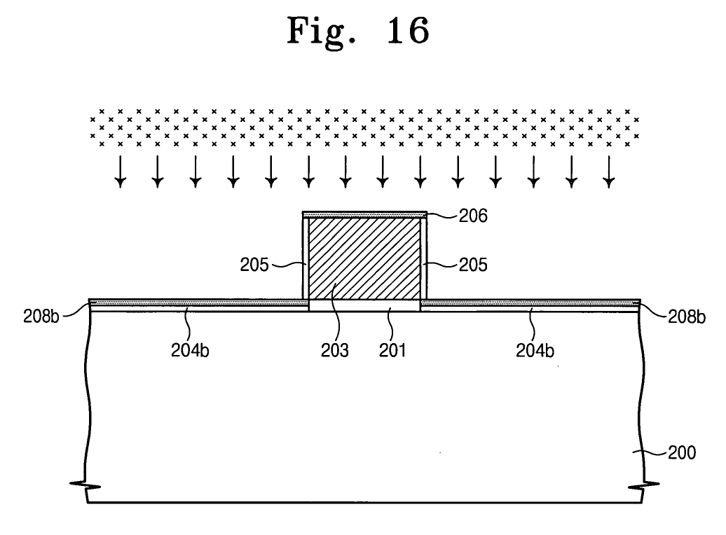

A mask layer may be formed over the substrate 200 before the plasma doping process is performed. The mask layer may be patterned, for example, using a photolithograpy process, to form a mask pattern layer. The charge storing layer 208a may be formed in a predetermined area on the substrate 200 using the mask pattern layer. The thermal treatment process in some embodiments is performed after the plasma doping process and the removal of the mask pattern layer. As will be described further herein with reference to FIGS. 15 and 16, it will be understood that the charge storing layer 208a may be formed using a buffer layer as described with reference to FIGS. 7a, 7b, 8a and 8b above.

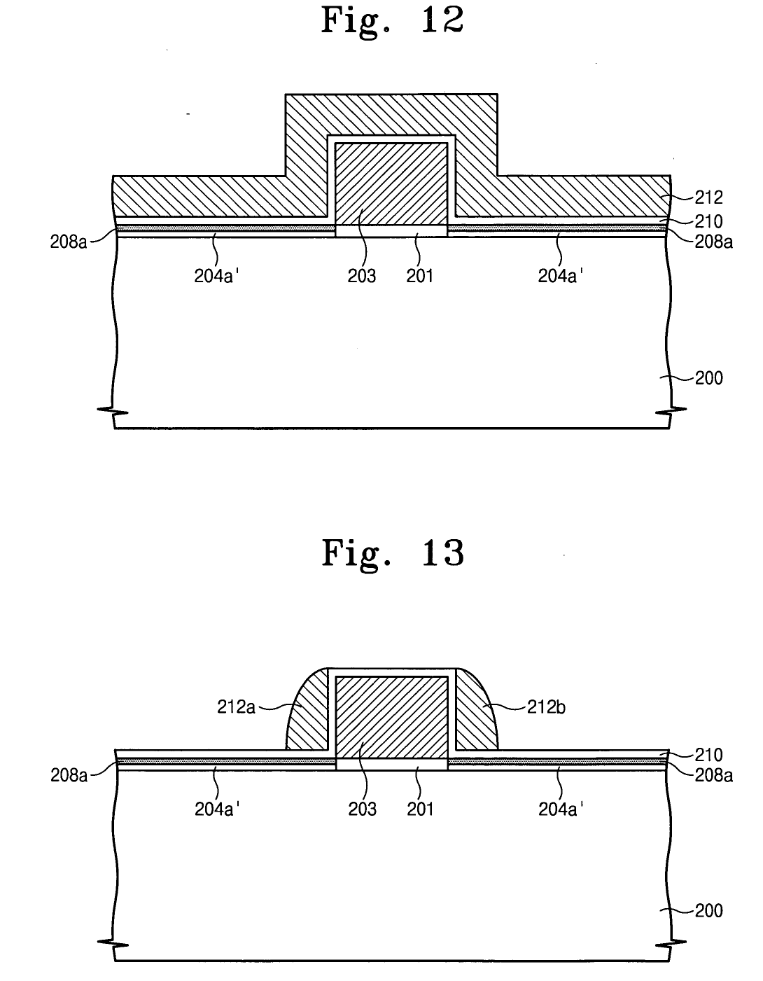

Referring now to FIG. 12, a blocking dielectric layer 210 is shown formed on the surface of the substrate 200 over the entire region including the charge storing layer 208a. The blocking dielectric layer 210 may be formed conformally on the substrate 200. As such, the blocking dielectric layer 210 may conformally cover opposite sidewalls and top surfaces of the charge storing layer 208a and the common gate electrode 203 as shown in FIG. 12. The blocking dielectric layer 210 may be formed using, for example, chemical vapor deposition (CVD).

The blocking dielectric layer 210 may be silicon oxide. In some embodiments where the blocking dielectric layer 210 is silicon oxide it may be thicker than the actual tunnel dielectric layer 204a′. In some embodiments, the blocking dielectric layer 210 may be made of a high-k dielectric material having a higher dielectric constant than the actual tunnel dielectric layer 204a′ where the tunnel dielectric layer may be a silicon oxide layer. For example, the blocking dielectric layer 210 may be made of a dielectric metal oxide, such as aluminum oxide, hafnium oxide and/or the like including combinations thereof.

A control gate conductive layer 212 is illustrated in FIG. 12 conformally formed on the blocking dielectric layer 210. The control gate conductive layer 212 may be doped polysilicon, metal (e.g., tungsten, molybdenum, etc.), conductive metal nitride (e.g., titanium nitride, tantalum nitride, etc.) and/or metal silicide (e.g., tungsten silicide, cobalt silicide, nickel silicide, and titanium silicide).

Referring now to FIG. 13, the control gate conductive layer 212 may be anisotropically etched until the blocking dielectric layer 210 formed on the common gate electrode 203 is exposed, forming a first control gate electrode 212a and a second control gate electrode 212b on opposite sides of and proximate the common gate electrode 203, respectively. The first and second control gate electrodes 212a and 212b may be similar to spacers formed on the opposite sidewalls of the common gate electrode 203 as shown in FIG. 13. The blocking dielectric layer 210 is interposed between the first control gate electrode 212a and one sidewall of the common gate electrode 203 and the second control gate electrode 212b and an opposite sidewall of the common gate electrode 203. The blocking dielectric layer 210 may thereby insulate the first and second control gate electrodes 212a and 212b from the common gate electrode 203.

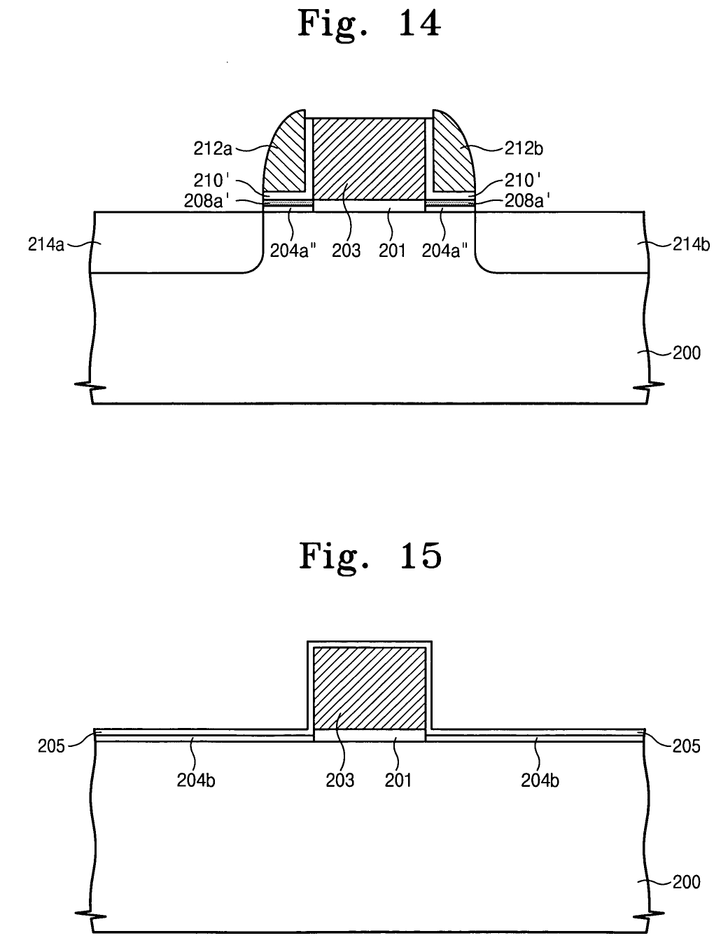

The first control gate electrode 212a may be configured in a memory device including the structure of FIG. 14 to provide a first non-volatile memory cell and the second control gate electrode 212b may be configured to provide a second non-volatile memory cell. In other words, the pair of the control gate electrodes 212a and 212b and the common control gate electrode 203 may be configured to operate as a pair of non-volatile memory cells.

Referring now to FIG. 14, the blocking dielectric layer 210, the charge storing layer 208a, and the actual tunnel dielectric layer 204a′ formed on the substrate 200 at opposite sides adjacent to the gate electrodes 212a, 203, and 212b may be successively etched using the common gate electrode and the first and second control gate electrodes 212a and 212b as etch masks. Thus, a tunnel dielectric pattern 204a″, a charge storing pattern 208a′, and a blocking dielectric pattern 210′ may be formed that are sequentially stacked between the first control gate electrode 212a and the substrate 200 as seen in FIG. 14. Likewise, such a sequentially stacked structure is formed between the second control gate electrode 212b and the substrate 200. When the blocking dielectric layer 210 on the opposite sides of the gate electrodes 212a, 203, and 212b is etched, the blocking dielectric layer 210 on the common gate electrode 203 may also be removed as shown in FIG. 14 to expose a top surface of the common gate electrode 203.

Using the gate electrodes 212a, 203, and 212b as masks, impurity ions may then be implanted to form a first impurity-doped layer (region) 214a and a second impurity-doped layer (region) 214b in the active region. The first impurity-doped layer 214a is shown adjacent the first control gate electrode 212a and the second impurity-doped layer 214b is shown adjacent the second control gate electrode 212a.

The impurity doped regions may be configured to provide respective source/drain regions of a transistor of a memory cell including the structure shown in FIG. 14. A non-volatile memory device including such a memory cell may use hot carrier injection in a program operation. For example, to program the first non-volatile memory cell, a voltage is applied to the gate electrodes 212a, 203 and 212b to turn on a channel, a ground voltage is applied to the second impurity-doped layer 214b, and a program voltage is applied to the first impurity-doped layer 214a. As a result, charges having the same type as major carriers in the impurity-doped layers 214a and 214b may be accelerated to the first impurity-doped layer 214a from the second impurity-doped layer 214b to generate hot carriers near the first impurity-doped layer 214a. Due to the presence of the hot carriers, the charges may be injected into the charge storing pattern 208a′ below the first control gate electrode 212a to program the first non-volatile memory cell. An erase operation of the non-volatile memory device may be conducted by means of FN tunneling and/or injection of hot carriers having an opposite conductivity type to stored charges.

A read operation of the non-volatile memory device will now be described for some embodiments. A read operation of the first non-volatile memory cell will first be described. A voltage is applied to the common gate electrode 203 and the second control gate electrode 212b to turn on underlying channel regions, and a sensing voltage is applied to the first control gate electrode 212a. Thus, data stored in the charge storing pattern 208a′ below the first control gate electrode 212a may be read out. The voltage applied to the second control gate electrode 212b may be higher than a programmed threshold voltage of the second non-volatile memory cell.

Using a read operation as described, data of the first non-volatile memory cell may be read out without regard to whether the second non-volatile memory cell is programmed. In methods according to some embodiments of the present invention as illustrated in FIGS. 10-14, the charge storing layers 208a and 208b may be formed by a plasma doping process as described above. Therefore, it is possible to obtain substantially the same effects as described with reference to the embodiments shown in FIGS. 1a to 6a and 1b to 6b. For example, it may be possible to freely adjust the density of specific elements in the charge storing layers 208a and 208b.

As such, characteristics of the charge storing layers 208a and 208b may be regulated to provide improvements in some embodiments and such improvements may provide charge storing layers 208a and 208b suitable for a highly integrated non-volatile memory device. As ions of a selected element may be readily implanted even with low energy in the plasma doping process, degradation of the tunnel dielectric layers 204a′ and 204b′ may also be reduced and characteristics of the charge storing layers 208a and 208b may be enhanced.

In some embodiments, using an anisotropic plasma doping process, the charge storing layer 208a and 208b may not be formed on opposite sidewalls of the common gate electrode 203. If a charge storing layer were formed on the opposite sidewalls of the common gate electrode 203, charges stored by a program operation may be stored in a charge storing layer formed on a sidewall of the common gate electrode 203. As such, it may be considerably more difficult subsequently to eliminate the charges stored in the charge storing layer formed on the sidewall of the common gate electrode 203 when re-programming the memory cell. Further, it may be very difficult to selectively remove only the portion of the charge storing layer formed on the sidewall of the common gate electrode 203. In other words, when the undesired charge storing layer formed on the sidewall of the common gate electrode 203 is removed, the desired charge storing layer formed on the substrate 200 at opposite sides adjacent to the common gate electrode 203 may also be removed.

Using the anisotropicity of the plasma doping process used in some embodiments of the present invention, a charge storing layer may not be not formed on the opposite sidewalls of the common gate electrode 203 or any layer so formed may have limited charge storing capacity. Therefore, it may be possible to limit or even prevent degradation or malfunction of a non-volatile memory device.

In addition, before the plasma doping process is performed, a mask pattern may be formed. Therefore, it is possible to form the charge storing layers 208a and 208b only in a selected predetermined area on the substrate 200.

As explained above, a charge storing layer may be formed by means of a plasma doping process to freely change a ratio of constituents in the charge storing layer and/or change the constituents relative to a CVD process or the like, where the ratio of constitutents is generally limited by the reaction process. The use of the plasma doping process may also allow changes in the density of a specific element more readily. As a result, characteristics of the charge storing layer may be readily regulated to achieve an improved charge storing layer.

In the plasma doping process, ions of a specific element can be implanted with a very low acceleration energy relative to an ion injection process. Thus, degradation of a tunnel dielectric layer below the charge storing layer may be reduced and characteristics of the charge storing layer can be enhanced. In addition, the plasma doping process generally may be performed more quickly for a given desired structure than the ion injection process while maintaining an ability to introduce a concentration of ions of the selected element to a target layer at levels exceeding and more controllable than is generally possible with a process such as CVD. Plasma doping also generally may provide a delta depth range of ions of the selected element in the target layer better than ion injection and close to that of a process such as CVD.

Plasma doping further provides greater selectivity in doping elements and better control of anisotropicity than a process such as CVD, which is generally isotropic regardless of process settings. As such, the charge storing layer may be formed having a desired property only in a desired region. This may further reduce degradation of the characteristics of a non-volatile memory device.

Further embodiments will now be described with reference to FIGS. 15 and 16. It will be understood that the embodiments of FIGS. 15 and 16 may proceed substantially the same as described with reference to the embodiments of FIGS. 10-14 except as described herein. As shown in FIG. 15, a tunnel dielectric layer 204b is formed over the substrate 200 on both sides of the common gate electrode 203. The tunnel dielectric layer 208a may be formed, for example, of a thermal oxide using a thermal oxidation process. The thickness of the tunnel dielectric layer 204b may be thinner than that of the tunnel dielectric layer 204a shown in FIG. 10. A buffer layer 205 is formed over the substrate 200 in the region including the tunnel dielectric layer 204b. As shown in FIG. 15, the buffer layer 205 may be conformally formed and may extend along sidewalls and an upper surface of the common gate electrode 203. In some embodiments, the plasma doping process uses a nitrogen gas as a source gas and the buffer layer 205 is formed as silicon oxide or a silicon layer. In some embodiments where the plasma doping process uses element(s) selected from group 4 of the periodic table, the buffer layer 205 is silicon oxide. The buffer layer 205 may be a high-k dielectric layer in some embodiments.

Referring now to FIG. 16, a plasma doping process is performed for the substrate 200 including the buffer layer 205. As a result, ions of a selected element are implanted into the buffer layer 205 to form a charge storing layer 208b on the tunnel dielectric layer 204b. The plasma doping process may be performed in a manner substantially the same as described previously, for example, with reference to FIGS. 2a and 2b.

The plasma doping process may be followed by an annealing process for the substrate 200. Accordingly, the charge storing layer 208b may be annealed (in a case where a source includes nitrogen) and a plurality of nano-crystal particles may be formed in the charge storing layer 208b to be spaced apart from one another to form a discrete charge storing layer. The annealing process may be performed substantially as described with reference to FIGS. 3a and 3b.

As discussed previously, as the ions of the selected element are implanted by means of an anisotropic plasma doping process in some embodiments, implanting of the ions into the buffer layer 205 formed on opposite sidewalls of the common gate electrode 203 may be limited or even prevented. As a result, the charge storing layer 208b need not be formed on the opposite sidewalls of the common gate electrode 203 and the structure illustrated in FIG. 16 may be formed.

The buffer layer 205 formed on a top surface of the common gate electrode may be subjected to ion implanting during the anisotropic plasma doping process and a capping layer 206 may be formed on the common gate electrode 203. The capping layer 206 may include the same material as the charge storing layer 208b.

Subsequent processes may be performed following the formation of the above-described charge storing layer 208a and 208b. Such processes may generally proceed as described with reference to FIGS. 12 through 14. In other words, such subsequent processes performed following the formation of the charge storing layer 208b may be substantially the same as the subsequent processes described as being performed following the formation of the charge storing layer 208a.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of forming an integrated circuit memory device, comprising:
forming a dielectric layer on a substrate;
forming a charge storing layer on an upper surface of the dielectric layer using a plasma doping process with a remaining portion of the dielectric layer under the charge storing layer defining a tunnel dielectric layer;
forming a blocking dielectric layer on the charge storing layer; and
forming a gate electrode layer on the blocking dielectric layer.

2. The method of claim 1, wherein forming the charge storing layer is preceded by forming a photoresist mask pattern on the tunneling dielectric layer having an opening thereon exposing the tunneling dielectric layer in a predetermined area and wherein forming the charge storing layer comprises forming the charge storing layer in the predetermined area using the photoresist mask pattern.

3. The method of claim 1, wherein forming the charge storing layer includes thermal treating the substrate after the plasma doping process.

4. The method of claim 1, wherein forming the charge storing layer comprises forming the charge storing layer using a plasma including ions of a selected element and at an acceleration energy of about 50 electron volts (eV) to about 5000 eV.

5. The method of claim 4, wherein the selected element comprises a nitrogen element.

6. The method of claim 5, wherein the nitrogen element is nitrogen gas (N₂), ammonia gas (NH₃) and/or nitrogen tri-fluroride gas (NF₃).

7. The method of claim 5, wherein a dose amount of the nitrogen element is about 1×10¹⁴/cm² to about 1×10¹⁷/cm².

8. The method of claim 5, wherein forming the charge storing layer includes rapid thermal treating the substrate after the plasma doping process at a temperature from about 800° C. to about 1100° C. in an atmosphere including oxygen, nitrogen, ammonia and/or hydrogen.

9. The method of claim 5, wherein forming a dielectric layer comprises forming a single dielectric layer having a thickness selected to result in a desired thickness of the tunnel oxide layer and the charge storing layer.

10. The method of claim 5, wherein forming a dielectric layer comprises:
forming a first dielectric layer; and
forming a second dielectric layer on the first dielectric layer;
wherein forming the charge storing layer comprises forming the charge storing layer in the second dielectric layer.

11. The method of claim 10, wherein:
forming a first dielectric layer comprises thermal oxidizing the substrate; and
forming the second dielectric layer comprises forming the second dielectric layer using a chemical vapor deposition (CVD) process.

12. The method of claim 5, wherein forming a dielectric layer comprises:
forming a lower dielectric layer; and
forming a high-k dielectric layer on the lower dielectric layer;
wherein forming the charge storing layer comprises exposing the high-k dielectric layer to a plasma including ions of a selected element to increase a density of trap sites in the high-k dielectric layer.

13. The method of claim 12, wherein the high-k dielectric comprises silicon nitride, hafnium oxide, tantalum oxide, titanium oxide and/or aluminum oxide.

14. The method of claim 12, wherein:
forming the lower dielectric layer comprises thermal oxidizing the substrate; and
forming the high-k dielectric layer comprises forming the high-k dielectric layer using a chemical vapor deposition (CVD) process.

15. The method of claim 4, wherein the selected element comprises an element selected from group 4 of the periodic table and wherein forming a charge storing layer includes thermal treating the substrate after the plasma doping process to form nano-crystallization particles defining the charge storing layer.

16. The method of claim 15, wherein the selected element comprises carbon gas, silicon gas and/or germanium gas.

17. The method of claim 15, wherein the selected element comprises a source gas of silane (SiH4), silicon tetracholoride (SiCl4), silicon tetrafluoride (SiF4), germanium tetrahydride (GeH4), germanium fluoride (GeF4), methane (CH4) and/or ethane (C2H6).

18. The method of claim 15, wherein thermal treating the substrate comprises rapid thermal treating the substrate at a temperature from about 800° C. to about 1100° C. in an atmosphere including oxygen, nitrogen, ammonia and/or hydrogen to form the nano-crystallization particles defining the charge storing layer.

19. The method of claim 15, wherein a dose amount of the selected element is about 1×10¹⁴/cm² to about 1×10¹⁷/cm².

20. The method of claim 15, wherein forming a dielectric layer comprises forming a single dielectric layer having a thickness selected to result in a desired thickness of the tunnel oxide layer and the charge storing layer.

21. The method of claim 15, wherein forming a dielectric layer comprises:
forming a first dielectric layer; and
forming a second dielectric layer on the first dielectric layer;
wherein forming the charge storing layer comprises forming the nano-crystallization particles in the second dielectric layer.

22. The method of claim 21, wherein:
forming a first dielectric layer comprises thermal oxidizing the substrate; and
forming the second dielectric layer comprises forming the second dielectric layer using a chemical vapor deposition (CVD) process.

23. The method of claim 15, wherein forming a dielectric layer comprises:
forming a lower dielectric layer; and
forming a high-k dielectric layer on the lower dielectric layer;
wherein forming the charge storing layer comprises exposing the high-k dielectric layer to a plasma including ions of a selected element to increase a density of trap sites in the high-k dielectric layer.

24. The method of claim 1, further comprising forming source and drain regions in the substrate on respective sides of the gate electrode layer.

25. The method of claim 2, wherein the selected element comprises boron gas, arsenic gas and/or phosphorous gas.

26. A method of forming an integrated circuit memory device, comprising:
forming a dielectric layer on a substrate;
forming a common gate electrode on the dielectric layer;
forming a charge storing layer on an upper surface of the dielectric layer using an anisotropic plasma doping process and using the common gate electrode as a mask, wherein a portion of the dielectric layer that is under the common gate electrode defines a common gate dielectric layer;
forming a blocking dielectric layer on the charge storing layer and the common gate electrode; and
forming control gate electrodes on the blocking dielectric layer on opposite sides of the common gate electrode.

27. The method of claim 26, wherein forming the charge storing layer includes thermal treating the substrate after the plasma doping process.

28. The method of claim 26, wherein forming the charge storing layer comprises forming the charge storing layer using a plasma including ions of a selected element at an acceleration energy of about 50 electron volts (eV) to about 5000 eV.

29. The method of claim 28, wherein forming the charge storing layer comprises forming the charge storing layer at a pressure of no more than about 30 mTorr.

30. The method of claim 28, wherein forming the charge storing layer comprises forming the charge storing layer using a plasma not including hydrogen.

31. The method of claim 28, wherein the selected element comprises a nitrogen element.

32. The method of claim 28, wherein the dielectric layer comprises silicon oxide (SiO2).

33. The method of claim 28, wherein the blocking dielectric layer comprises a metal oxide.

34. The method of claim 28, wherein the control gate electrode layer comprises a doped poly-silicon layer and/or a metal layer.

35. The method of claim 34, wherein the control gate electrode layer comprises tungsten (W), molybdenum (Mo), titanium (Ti), tantalum (Ta), cobalt (Co), nickel (Ni) and/or a nitride or silicide thereof.

36. The method of claim 34, wherein the common gate electrode is formed of a same material as the control gate electrode layer.
